(19) United States
(12) Patent Application Publication
(10) Pub. No.: US 2007/0025240 A1
(43) Pub. Date: Feb. 1, 2007

(54) Bypass switch for an ethernet device and method of bypassing devices in an ethernet network

(76) Inventor: Todd A. Snide, Pelham, NH (US)

Correspondence Address: WALLENSTEIN & WAGNER, LTD., 311 SOUTH WACKER DRIVE, 53RD FLOOR, CHICAGO, IL, 60606, US

(21) Appl. No.: 11/192,909

(22) Filed: Jul. 29, 2005

(51) Int. Cl. G01R 31/08

(52) U.S. Cl. 370/217

(57) ABSTRACT

A network comprises a plurality of network devices, including a first network device coupled to a second network device and a third network in a daisy chain topology configuration. The first network device has a first device port connected to a first network port and a second device port connected to a second network port. A bypass switch is coupled to the first network device and creates a bypass path when the first network device is inoperable. The bypass switch is coupled to a processor in the first network device. The processor has a control function for closing the bypass path when the first network device is inoperable and for opening the bypass path when the first network device is operable. The bypass switch connects the first network port to the second network port when the device is inoperable.

### CROSS-REFERENCE TO RELATED APPLICATIONS

None.

### TECHNICAL FIELD

The invention generally relates to bypassing a network device on an Ethernet network having a daisy chain topology, and more particularly, the invention relates to bypass switch for creating a bypass path when the network device is inoperable and to a method for bypassing the network device.

### BACKGROUND OF THE INVENTION

In an Ethernet network, failure of one device can have a devastating affect on the information flow through the entire network. This is particularly true on a daisy chain topology network where the information is passed through one device to another.

Generally, in a daisy chain topology each network device is connected to a device upstream and downstream from itself. The daisy chain topology allows computers and other peripheral devices to be easily connected to a network and requires relatively less cable length than other network topologies. However, there are several disadvantage to employing a daisy chain topology. For example, any device failure in the chain will disable the entire network and prevent the transmission of all information on the network. Additionally, if a device needs to be added in the middle of the chain, the entire network will be disabled while the new device is added.

In order to overcome the failure of a single device causing the failure of the entire network, a star topology may be employed. In a star topology, each device has a cable leading back to a central hub. The most popular networks using a star topology are 10BASE-T Ethernet and Token Ring. A star network can simplify troubleshooting because devices can be disconnected from the hub one at a time until the problem is isolated without disabling the entire network. However, a star topology requires the added expense of a hub and utilizes more cable than a daisy chain topology which adds to the expense of the system. In addition, a hub failure can knock out the entire network.

The present invention is provided to solve the problems discussed above and other problems, and to provide advantages and aspects not provided by prior networks of this type. A full discussion of the features and advantages of the present invention is deferred to the following detailed description, which proceeds with reference to the accompanying drawings.

### SUMMARY OF THE INVENTION

The present invention relates to an Ethernet network having a daisy chain topology. The network comprises a first network device coupled to a second network device and a third network device in a daisy chain topology configuration. The first network device has a first device port connected to a first network port and a second device port connected to a second network port. Additionally, the first network device may be coupled to a plurality of network devices in a daisy chain topology configuration.

To avoid a failure of the network due to a problem with the first network device, a bypass switch is coupled to the first network device and creates a bypass path when the first network device is inoperable. The bypass switch may be coupled to a processor in the first network device. The processor has a control function for closing the bypass path when the first network device is inoperable and for opening the bypass path when the first network device is operable. The bypass switch connects the first network port to the second network port when the device is inoperable.

The bypass switch can be integrally part of the network device or it can be located on a removable adapter. The removable adapter has a first connector for connecting to a power source and a second connector for connecting to the first network device. The first and second connectors can be used to transmit network information between the first network device and other network devices. The second connector has a plurality of conductors, including one conductor for controlling power supplied to the removable adapter. The power source supplies power to the removable adapter when the removable adapter is connected to the first network device thereby disabling the bypass path. This power source may be located on the first network device.

According to another aspect of the invention, the present invention further includes a network device on an Ethernet network having a daisy chain topology. The network device may be coupled to a plurality of network devices in the daisy chain topology configuration. The network device includes a first device port for coupling the network device to a second network device in a daisy chain topology configuration and a second device port for coupling the network device to a third network device in a daisy chain topology configuration.

The network device also includes a bypass switch for creating a bypass path when the network device is inoperable. The bypass switch is coupled to a processor in the first network device. The processor has a control function for closing the bypass path when the first network device is inoperable and for opening the bypass path when the first network device is operable. The bypass switch connects the first network port to the second network port when the device is inoperable.

According to yet another aspect of the invention, the present invention further includes a method for creating a bypass path on an Ethernet network having a daisy chain topology. The method includes for providing a first network device includes a first device port connected to a first network port and a second device port connected to a second network port. The method further includes connecting the first network device to a second network device and a third network in a daisy chain topology configuration and coupling the first network device to a bypass switch. The method includes creating a bypass path connecting the first network port to the second network port when the first network device is inoperable. The method may further include coupling the first network device to a plurality of network devices in a daisy chain topology configuration and locating the bypass switch on a removable adapter.

The method further includes removing the first network device from the network and connecting a fourth network device to the network in place of the first network device. Additionally, the method includes disabling the bypass path in response to the fourth network device being operable.

Other features and advantages of the invention will be apparent from the following specification taken in conjunction with the following drawings.

### BRIEF DESCRIPTION OF THE DRAWINGS

To understand the present invention, it will now be described by way of example, with reference to the accompanying drawings in which:

FIG. 1 is a block diagram of a daisy chain Ethernet topology utilized in an industrial automation network;

FIG. 2 is a block diagram of a daisy chain Ethernet topology having network devices comprising a bypass switch in accordance with the present invention;

FIG. 3 illustrates a bypass switch implemented directly on a network device;

FIG. 4 illustrates a removable adapter having a bypass switch located thereon;

FIG. 5 illustrates power activation on the removable adapter of FIG. 4;

FIG. 6 illustrates an IP67 removable adapter;

FIG. 7 illustrates an IP20 removable adapter using four-wire cabling;

FIG. 8 illustrates an IP20 removable adapter using eight-wire cabling; and,

FIG. 9 illustrates a removable adapter connected to a network device through an external power connection.

### DETAILED DESCRIPTION

While this invention is susceptible of embodiments in many different forms, there is shown in the drawings and will herein be described in detail preferred embodiments of the invention with the understanding that the present disclosure is to be considered as an exemplification of the principles of the invention and is not intended to limit the broad aspect of the invention to the embodiments illustrated.

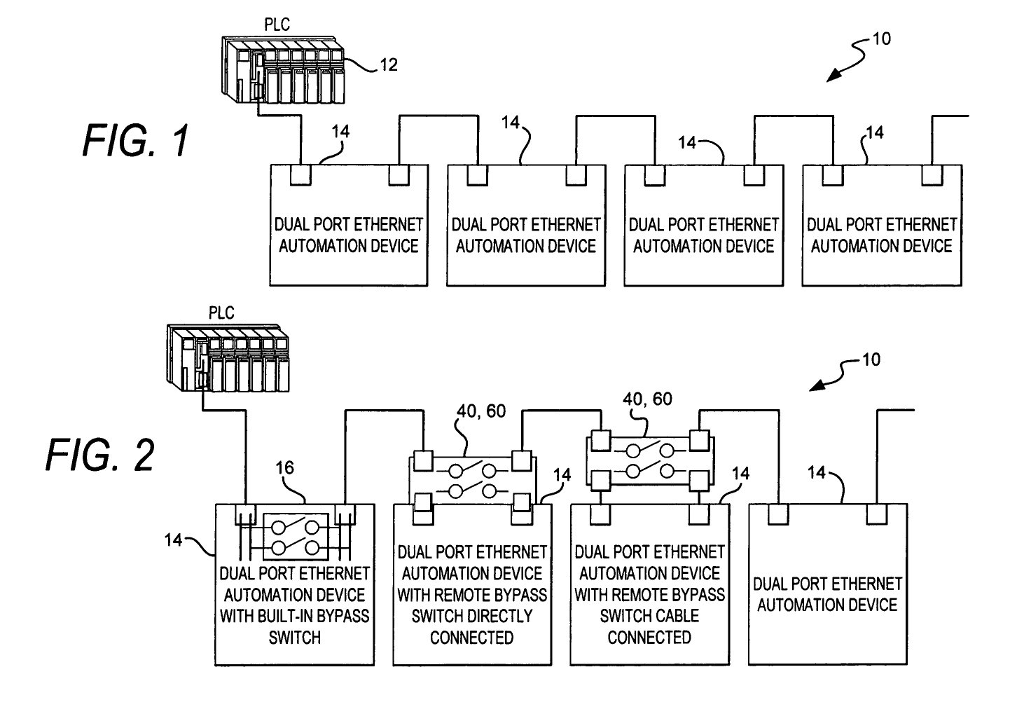

FIG. 1 illustrates a daisy chain Ethernet topology that is typically utilized in an industrial automation network 10. The network 10 is controlled by a PLC 12 which is coupled to a plurality of network devices 14, such as network automation devices. Preferably, the PLC 12 is coupled to the network devices 14 using 10/100 megabits per second Ethernet copper cabling. Each network device 14 is coupled to the next using a connector 20, such as an Ethernet connection, having a transmit port and receive port. Messages to and from the PLC 12 are transmitted through network devices 14 and must travel through all the network devices 14 between the PLC 12 and the network device 14 the message originated from or is intended for. However, if one of the network devices 14 between the PLC 12 and the network device 14 the message originated from or is intended for fails, the network 10 is disabled and the message will not be delivered.

Referring to FIG. 2, the present invention overcomes the problems associated with prior daisy chained networks by providing a daisy chain Ethernet topology having network devices 14 comprising or coupled to a bypass switch 16. The bypass switch 16 is utilized to prevent data loss on the Ethernet network 10 due to loss of devices by creating a bypass path. That is, the traffic path of data on the network 10 is maintained in the event that one or more of the plurality of network devices 14 becomes inoperable. It is preferable that all the network devices 14 include the bypass switch 16 such that if any network device 14 fails, the network 10 will continue to function.

As will be described herein, there are several embodiments implementing the bypass path 16 on a network device 14. In one embodiment, the bypass switch 16 is incorporated as an integral component directly of the network device 14. In another embodiment, the bypass switch 16 is implemented on a separate adapter 40,60 that is removably connected directly to the network device 14. In yet another embodiment, the bypass switch 16 is implemented on a separate adapter 40,60 that is connected to the network device 14 by a cable 63,65.

The bypass switch 16 may be a traditional relay such as reed type or optomos relay. An optomos relay operates based on optical CMOS technology. The optomos relay provides excellent emissions and immunity capability along with a nearly unlimited number of switching operations. Using normally closed and/or normally opened paths, information passed through the transmit 17 and receive 18 ports of connectors 20 can be sent from one port to another port or back out the same port in the event of partial or total power failure of the device 14. This bypass path would allow traffic to continue to move across the network without delay.

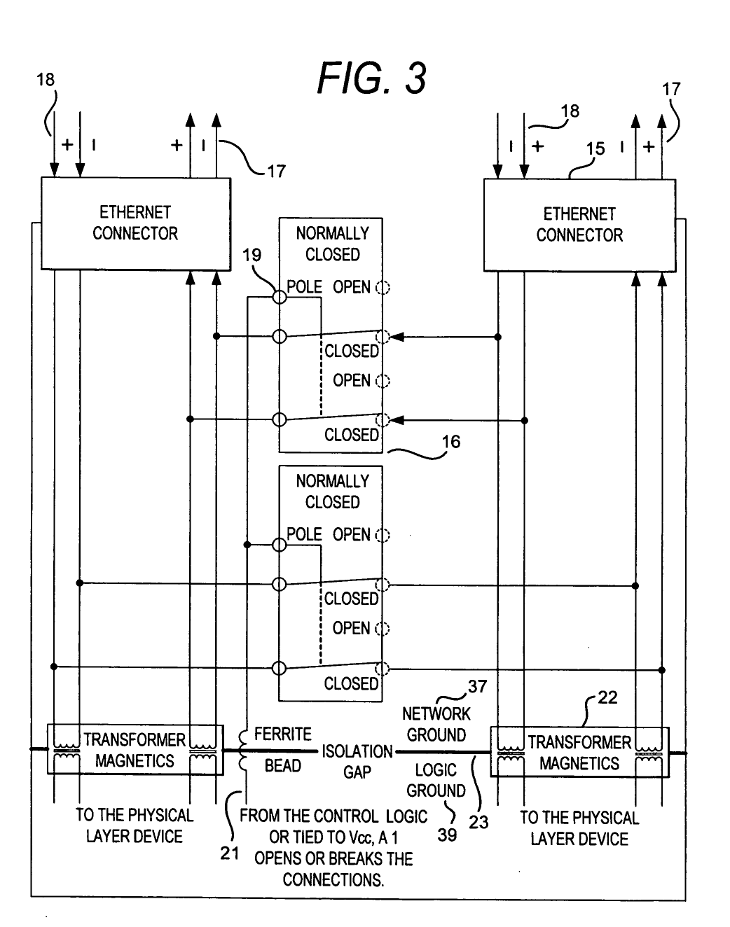

As illustrated in FIG. 3, in one embodiment, the bypass switch 16 is incorporated directly in the network device 14. Specifically, the bypass switch 16 is located on a Media Device Interface (MDI) bus (not shown) between the connectors 20 and the respective network isolation components 22, such as transformers. The bypass switch 16 utilized is a normally closed switch and may be of several types, as generally known by those skilled in the art. When the network device 14 is inoperable, such as not being powered or being broken, the normally closed bypass path is connected. Any traffic entering one of the ports 17,18 of the connector 20 is sent back out the respective port 17,18 on the other connector 20 without being transmitted through the network isolation component 22. It is important to note that the bypass switch 16 connects the receive port of one connector 20 to the transmit port of the other connector 20. Further, it is also important that the polarity be correctly maintained such that the negative stream remains connected to the negative stream and the positive stream remains connected to the positive stream.

The network device 14 may be in a bypass mode or an operational mode. The network device 14 automatically enters the operational mode when the power on the network device 14 is stable and at an adequate level. Conversely, the network device 14 automatically enters a bypass mode with the loss of power or when the network device 14 is otherwise inoperable.

If the network device 14 is in operational mode and power is applied to the network device 14, the pole control 19 of the bypass switch 16 is brought to a logical one and the bypass path will be broken allowing the connectors 20 to operate normally. This may be done automatically by power from the network device 14 through a control line 21 or may be part of a control function by the processing logic of the network device 14 through the control line 21, or a combination of both. In addition, the processing logic can place the network device 14 in bypass mode at any time during operation if desired.

The control function of the bypass switch 16 requires the bypass switch 16 to be powered in order to be taken out of its normal state, thereby putting the network device 14 into bypass mode. It is preferable that the normal state of the bypass switch 16 is closed such that when the device 14 is not powered the information path of the device 14 is bypassed. When a logical one is driven to the control pin 21 of the bypass switch 16, the switch 16 will be in an open state, thereby taking the device 14 out of bypass mode and into operational mode.

The control line 21 to the pole control 19 of the bypass switch 16 may be managed by a general purpose I/O pin (not shown) from any source such as a Physical Layer chip, a MAC chip, or a processor, etc (not shown). This permits the network device 14 to be taken in and out of the information path as desired. In addition, loss of power will automatically cause the device 14 to enter a bypass mode. The control line 21 may also be tied to the power of a processor (not shown) on the network device 14 such that when the processor has power the information path will open and the network device 14 will turn off the bypass path.

It is noted that proper isolation be maintained between the network ground 37, where the Ethernet connectors 22 reside, and the logic ground 39 where the rest of the device components reside on the control line 21 to insure no unwanted emissions cross between the two ground planes. This isolation may be provided with a ferrite bead 23 using a DC logic state signal to control the bypass switch 16. The use of a ferrite bead 23 is preferable if the control line 21 is tied to power and not to the general purpose I/O pin (not shown).

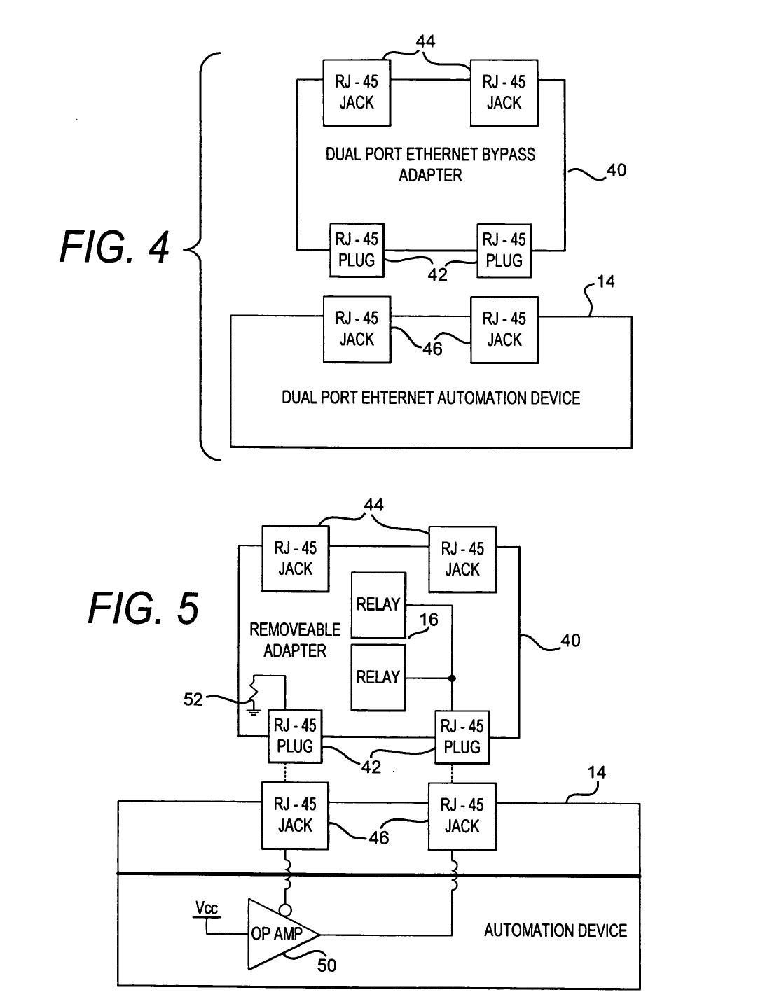

In instances where the bypass switch 16 is implemented directly on the network device 14, the information path may be disrupted while a failed network device 14 is replaced. To overcome this disruption of the information path for the replacement or repair of a failed device, the bypass switch 16 may be located on a removable adapter 40, as shown in FIG. 4. Although the bypass switch 16 is located on a removable adapter, it comprises substantially the same structure and functionality of a bypass switch 16 located directly on the network device 14.

When a network device 14 fails, it is separated from the adapter 40. The adapter 40 remains connected to the Ethernet cables from the network 10 leaving the information path intact. When the failed network device 14 is fixed or replaced, the network device 14 is reconnected to the network 10 through the removable adapter 40, thereby reestablishing the network device 14 into the network 10.

Referring to FIG. 4 the removable adapter 40 can be incorporated in an IP20 environment or a IP67 environment. Preferably, the removable adapter 40 has male connectors 42 on the side of the adapter 40 connected to the jacks 46 of the network device 14 and female connectors 44 on the side of the adapter connected to the network 10. The size of the adapter 40 is dominated by the size of the male and female connectors 42, 44. The bypass switch 16 located within the adapter 40 and any associated logic would take up relatively little space in comparison.

IP20 is an industrial automation designation describing a relatively benign environment where the components inside of that environment are not required to be sealed against the hazards of the environment. The IP20 removable adapter 40 comprises two board-mounted male RJ-45 connectors 42, two board-mounted RJ-45 receptacles 44, the bypass switch 16, a board (not shown) and a housing enclosing the components.

Power to the removable adapter 40 may come from the network device 14 to which the adapter 40 will be connected. However, it is noted that the adapter may be powered by any means known to those of ordinary skill in the art. Preferably, the removable adapter 40 is not continuously powered as this may affect the Ethernet signal in a network 10 that does not support or use the removable adapter 40. As a result, the present embodiment permits power to the be supplied to the removable adapter 40 from the supporting network device 14 when connected to the supporting network device 14 and the power to be inhibited from use when the removable adapter 40 is not present.

The male and female RJ-45 connectors 42, 44 can support eight conductors. However, Ethernet information is sent on only four conductors for 10/100 Ethernet. As a result, the remaining four conductors may be set up to allow a simple resistor logic to act as an enable/inhibit line (not shown). One pin from the unused pins on one of the RJ-45 connectors 42 is the enable/inhibit line. Another pin from the unused pins of the RJ-45 connectors 42 is used to drive the control logic of the bypass switch 16. When the network device 14 detects that the removable adapter 40 is connected and power is present on the network device 14, the network device 14 opens the bypass path on the bypass switch 16.

FIG. 5 illustrates power activation on a removable adapter 40. The network device 14 comprises power drive circuitry 50, such as an Op Amp 50 or other non-inverting driver, to supply power to the removable adapter 40 over one of the unused pins of one of the RJ-45 connectors 42. The Op Amp 50 drives power to the removable adapter 40 and the enable/inhibit signal is brought low with the connection of the removable adapter 40 to the network device 14.

The removable adapter 40 of the present invention may be inserted to and removed from the network device 14 when power is being applied to the network device 14. Precautions maybe necessary to protect against in-rush current as the IP20 removable adapter 40 is inserted or connected to the network device 14 when the network device 14 is powered. As a result, the removable adapter 40 may comprise circuitry 52 to protect against in-rush current to the power and ground of the bypass switch 16. Generally, the amount of current to drive the bypass switch 16 is low, thus small value resistors may be utilized if required.

The circuit 52 of the IP20 removable adapter 40 to protect against in-rush current to the power and ground of the bypass switch 16 may be a pull-up resistor 52. The output of the power drive circuitry 50 is coupled to the pull up resistor 52 to prevent driving the power out the RJ-45 connector 46 if the removable adapter 40 is not present. When the pull up resistor 52 is used and the adapter 40 is not in use, the output of the power drive circuit 50 uses a transistor or other logic (not shown) to isolate the pull up resistor 52 from the RJ-45 connector 46. If a transistor or other logic is not used, the network device 14 may drive a DC voltage level over the RJ-45 connector 46 when the adapter is not in use. The network device 14 has an adaptable termination on the unused pins from the RJ-45 connector 46 to allow the use of enable/inhibit logic and the power logic. Typically some form of termination, such as the “Bob Smith” termination described in U.S. Pat. No. 5,321,372, is employed on unused pins in the Ethernet connection.

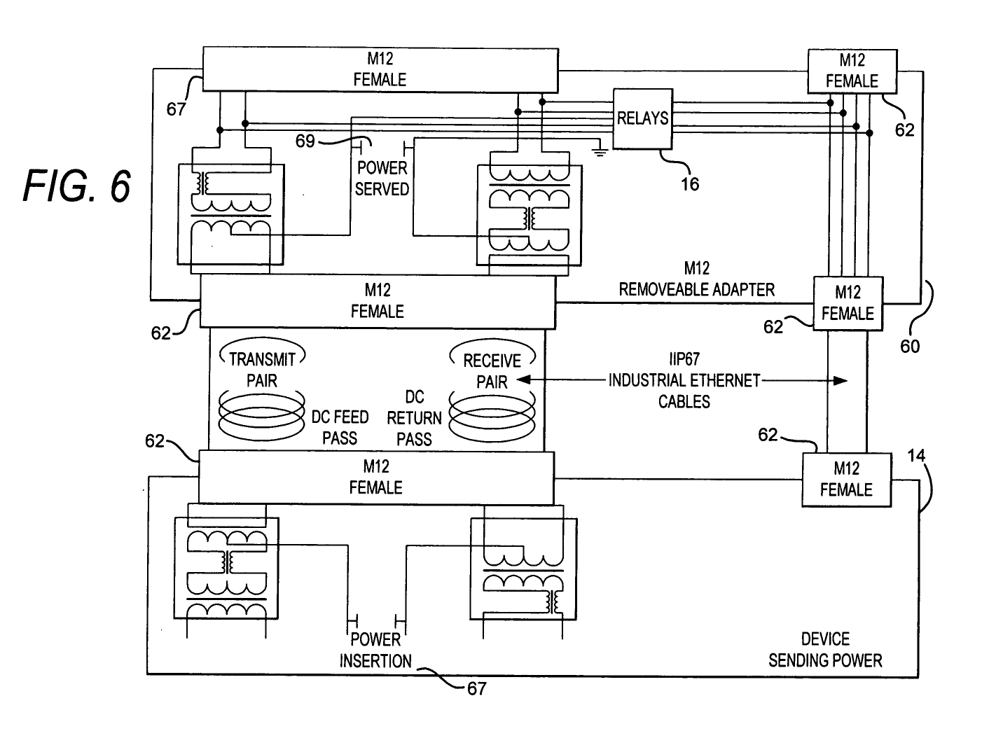

As set forth above, an IP67 removable adapter 60 can be utilized, as illustrated in FIG. 6. IP67 is an industrial automation designation describing a relatively harsh environment where the components inside of that environment are required to be sealed against the hazards of the environment. Unlike the IP20 removable adapter 40, the IP67 removable adapter 60 utilizes M12 connectors 62. The M12 connector 62 is a type of connector with male and female components used in IP67 environments, that when connected together, seal the device and the cable from the outside elements.

The M12 connectors 62 used in industrial networks have four pins and no extra pins upon which to send the enable/inhibit signal and the power. Therefore the enable/inhibit signal and power to the bypass switch 16 must be sent over two pins with the data. Consistent with this design, the enable/inhibit signal can not be a simple pull down resistor to ground since this would ground the data signal.

In order to solve this problem, the network device 14 may have a power injector 67 to send power over a data pin if the power is terminated on the adapter 60. This is to ensure that no power is leaked over the network 10 to the next network device 14. The power injector 67 may be power over Ethernet which allows the electrical current necessary for the operation of each adapter 60 to be carried by the data cables rather than by power cords.

In addition, the power injector can use an isolated driver (not shown), similar to the non-inverting driver 50 discussed above. This minimizes the number of wires that must be used in order to install the network 10. The result is lower cost, less downtime, easier maintenance, and greater installation flexibility than with traditional wiring.

Similar to the IP20 removable adapter 40, precautions maybe necessary to protect the IP67 removable adapter 60 against in-rush current as it is inserted or connected to the network device 14 when the network device 14 is powered. Thus, the IP67 removable adapter 60 can include built in circuitry 69 to protect against in-rush current if it uses a power over Ethernet style power insertion. The amount of power driven to the IP67 removable adapter 60 is minimal and does not need to be sent off the adapter 60. As such, the IP67 removable adapter 60 may include a cost effective low-drive tap 69.

In yet another embodiment, the bypass switch 16 is implemented on separate removable adapter that is cabled to the network device 14. The removable adapter 40 may be a IP20 removable adapter 40 or a IP67 removable adapter 60. Additionally, the removable adapter 40,60 may be coupled to the network device 14 using four-wire cabling of eight-wire cabling.

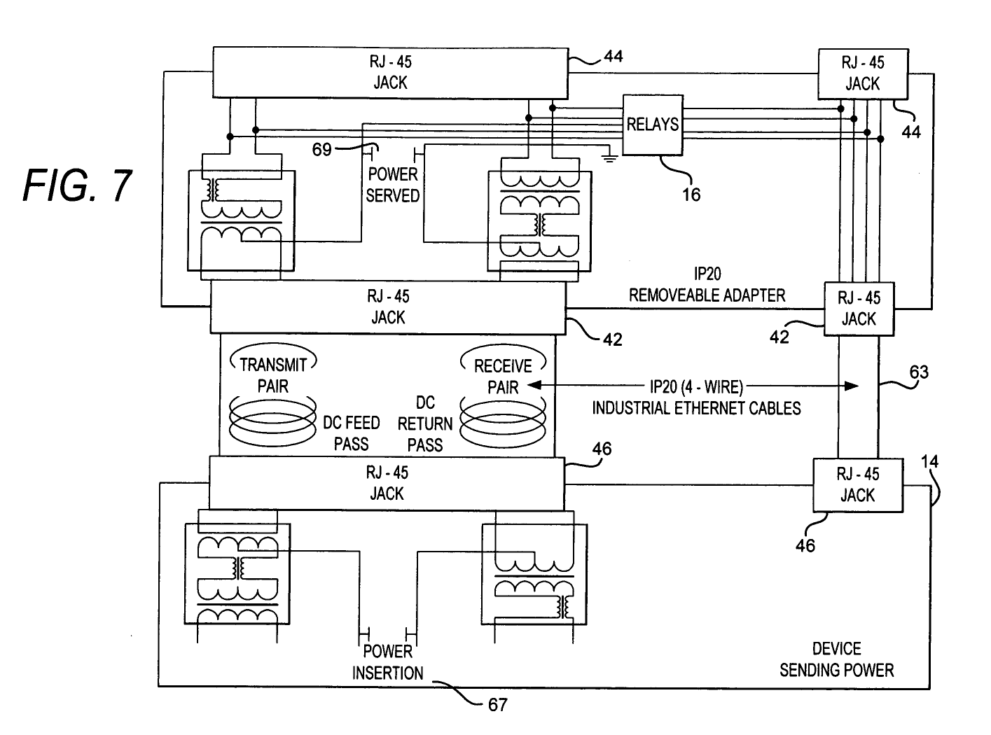

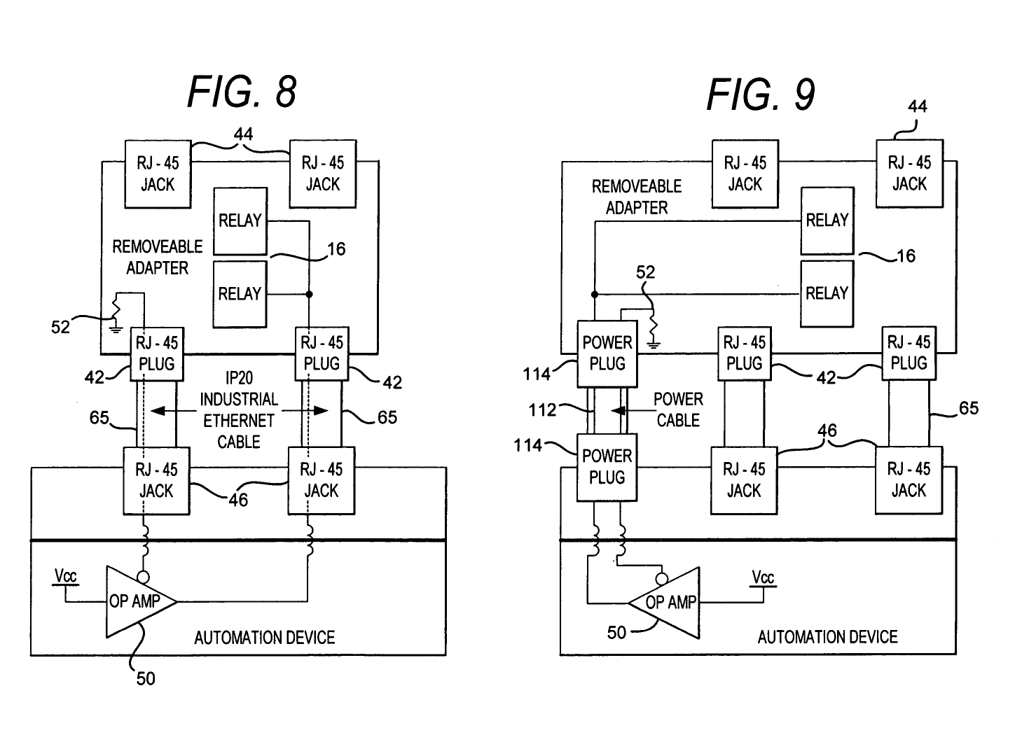

FIG. 7 illustrates an IP20 removable adapter 40 using four-wire cabling and FIG. 8 illustrates an IP20 removable adapter using eight-wire cabling. With reference to FIG. 7, the IP20 removable adapter 40 is coupled to the network device 14 utilizing IP20 (four-wire) industrial Ethernet cables 63. Preferably, a four-wire version CAT-5E Ethernet cable, as those typically employed in industrial automation, is utilized to connect the removable adapter 40 to the network device 14. In the network 10 of FIG. 7, male RJ-45 connectors 42 are attached to the ends of the industrial Ethernet cable 63. The same power injection 67 employed in the IP67 removable adapter 60, as described above, is used in the IP20 removable adapter 40 because only four conductors are available in this configuration of the Ethernet cable 63. Additionally, built in circuitry 69 similar to the IP67 removable adapter 60 can be utilized to protect against in-rush current.

Referring to FIG. 8, the IP20 removable adapter 40 utilizes an eight-wire Ethernet cable 65 to couple the removable adapter 40 with the network device 14. In the removable adapter 40 of FIG. 8, male RJ-45 connectors 42 are attached to the ends of the Ethernet cable 65. The RJ-45 connectors 42 support eight conductors. Ethernet information is transmitted on four conductors for 10/100 Ethernet. As a result, the remaining four conductors are set up to allow a simple resistor logic 52 to act as an enable/inhibit line to the network device 14, in a manner similar to that described above.

It is also contemplated that the power injection 67 utilized in the IP20 removable adapter 40 using four-wire cabling may also be utilized in the an IP20 removable adapter 40 using eight-wire cabling. Similarly, low-drive tap 69 may also be utilized in the IP20 removable adapter 40 using eight-wire cabling.

In another embodiment, an external power connection 112 separated from the Ethernet connection connects the removable adapter 40, 60 to the network device 14, as shown in FIG. 9. The external power connection 112 is utilized to detect and use power from the network device 14 that is to be protected or bypassed. The external power connection 112 may be utilized with both the IP20 removable adapter 40 and the IP67 removable adapter 60. The removable adapters 40,60 may include built-in circuitry 52 to protect against in-rush current.

When utilized with an IP20 removable adapter 40, the external power connection 112 uses a standard bullet plug to connect the network device 14 to the removable adapter 40. The external power connection 112 should use power cables that are rated for use in an IP20 environment. Preferably, the external power connection 112 has two male ends that connect to corresponding female power acceptors 114 on the network device 14 and the removable adapter 40. In another embodiment, the external power connection 112 may be a single wire connecting a screw terminal on the network device 14 to a screw terminal on the removable adapter 40.

As noted, the external power connection 112 may also be utilized with an IP67 removable adapter 60. In the IP67 environment, the power acceptors 114 on the network device 14 and the adapter 40 must be sealed against the environment. In addition, the external power connection 112 should use power cables that are rated for use in an IP67 environment.

The adapters 40,60 may be physically secured to the network device 14 to which they are providing a bypass path. In an IP67 environment, only two attach points (not shown) are used as securing connections because the adapter 60 is relatively small and the M12 connectors 62 provide a very secure connection. However, a screw connection, or other type of fastener, on the IP67 adapter 60 that mates with a corresponding connector on the network device 14 may be utilized to provide addition attachment. An IP20 adapter 40 may be secured using the RJ-45 connectors 42. Additional connections may be utilized to secure the IP20 adapter 40 to the network device 14 and provide protection against light stress or vibration loads. Female connectors may be used for all connections on the removable adapter 40,60 and network devices 14. Standard cables may be used to connect the network device 14 and the removable adapter 40,60 thereby allowing convenient mounting.

Similar to the control line 21 of the bypass switch 16 residing directly on the network device, the control line (not shown) to the removable adapter 40, 60 may be controlled by the power status of the network device 14. For example, if the network device 14 is sufficiently powered, the removable adapter 40,60 is automatically taken out of bypass mode. Control may also be handled by intelligent logic on the network device 14 that places the removable adapter 40,60 into bypass mode if desired even though the network device 14 is powered. This may be used to perform maintenance on the network device 14 without removing the network device 14 from the network 10.

When the removable adapter 40,60 is connected to the network device 14 and the network device 14 is initially powered up, there is a need to ensure the network device 14 does not interrupt the current traffic on the network 10. Firmware may be used to control the introduction of the network device 14 back into the network 10. If the network 10 is busy when the network device 14 is inserted into the adapter 40,60, the network device 14 will become active on the network 10 at an appropriate time that does not affect the flow of traffic on the network 10.

Preferably, the network device 14 includes logic to make an intelligent decision as to when it becomes active on the network 10. Normally open relays on the signals going to and from the network device 14 within the removable adapter 40,60 may be used to ensure the network device 14 does not improperly drive or take control of the Ethernet connectors before the system is ready to pass control to the network device 14 or accept Ethernet traffic from the network device 14. The transmit path on the removable adapter 40,60 (which is the receive path on the network device 14) may not require the normally open relays because the network device 14 does not drive these signals. Allowing the transmit paths to the network device 14 to be open will permit the network device 14 to snoop the traffic on the network 10. The snooping capability permits the network device 14 to participate in the decision as to when to become active on the network 10.

While the specific embodiments have been illustrated and described, numerous modifications come to mind without significantly departing from the spirit of the invention, and the scope of protection is only limited by the scope of the accompanying Claims.

What is claimed is:

1. An Ethernet network having a daisy chain topology, the network comprising:
a first network device coupled to a second network device and a third network in a daisy chain topology configuration; and,
a bypass switch coupled to the first network device wherein the bypass switch creates a bypass path when the first network device is inoperable.

2. The network of claim 1 further comprising a plurality of additional network devices coupled to the first, second and third network device in a daisy chain topology configuration wherein the second, third and additional network devices each comprise a bypass switch.

3. The network of claim 1 wherein the bypass switch is integrally incorporated in the first network device.

4. The network of claim 1 further comprising a first network port connected to a first device port in the first network device and a second network port connected to a second device port in the first network device wherein the bypass path connects the first network port to the second network port when the device is inoperable.

5. The network of claim 1 wherein the bypass switch is coupled to a processor in the first network device, the processor having a control function for controlling the bypass switch.

6. The network of claim 1 wherein the bypass path is closed when the first network device is inoperable and the bypass path is open when the first network device is operable.

7. The network of claim 1 wherein the bypass path is closed when power is not supplied to the bypass switch.

8. The network of claim 1 wherein the bypass switch is located on a removable adapter, the removable adapter comprising:
a first connector connecting to a power source; and,
a second connector for removably connecting the removable adapter to the first network device, the connector having a conductor for controlling power supplied to the removable adapter.

9. The network of claim 8 wherein the removable adapter is connected to the first network device by a cable.

10. The network of claim 8 wherein the removable adapter is plugged directly into the first network device.

11. The network of claim 8 wherein the power source supplies power to the removable adapter when the removable adapter is connected to the first network device and disables the bypass path.

12. The network of claim 8 wherein the power source is located on the first network device.

13. The network of claim 8 wherein at least one of the first connector and second connector transmits network information.

14. A network device on an Ethernet network having a daisy chain topology, the network device comprising:
a first device port for coupling the network device to a second network device in a daisy chain topology configuration;
a second device port for coupling the network device to a third network device in a daisy chain topology configuration; and,
a bypass switch for creating a bypass path between the first device port and the second device port when the network device is inoperable.

15. The network device of claim 14 wherein the network device is coupled to a plurality of network devices in a daisy chain topology configuration wherein each of the plurality of network devices comprise a bypass switch.

16. The network device of claim 14 further comprising a processor in the network device, the processor having a control function for controlling the bypass switch.

17. The network device of claim 14 wherein the first device port is connected to a first network port and the second device port is connected to a second network port and the bypass path connects the first network port to the second network port when the device is inoperable.

18. The network device of claim 14 wherein the bypass path is closed when the network device is inoperable and the bypass path is open when the network device is operable.

19. The network of claim 14 wherein the bypass path is closed when power is not supplied to the bypass switch.

20. The network device of claim 14 further comprising a connector for connecting to a power source for applying power to the network device, wherein the bypass path is open when power is applied to the network device.

21. A method for creating a bypass path on an Ethernet network having a daisy chain topology, the method comprising:
connecting a first network device to a second network device and a third network in a daisy chain topology configuration, the first network device coupled to a bypass switch;
detecting when the first network device is inoperable; and
creating a bypass path in response to the first network device being inoperable.

22. The method of claim 21 wherein the first, second and third network devices are coupled to a plurality of additional network devices in a daisy chain topology configuration wherein the second, third and additional network devices each comprise a bypass switch.

23. The method of claim 21 wherein the bypass switch is located on a removable adapter attached to the first network device by a cable.

24. The method of claim 21 wherein the bypass switch is plugged directly into the first network device.

25. The method of claim 21 further comprising the steps of:
removing the first network device from the network;
connecting a fourth network device to the network in place of the first network device; and,
disabling the bypass path in response to the fourth network device being operable.

26. The method of claim 21 wherein the first network device comprises a first device port connected to a first network port and a second device port connected to a second network port further comprising the step of:
connecting the first network port to the second network port when the first network device is inoperable.
